(19) United States
(12) Patent Application Publication
(10) Pub. No.: US 2025/0104752 A1
(43) Pub. Date: Mar. 27, 2025

(54) NON-VOLATILE SEMICONDUCTOR MEMORY DEVICE, SYSTEM ON CHIP USING THE MEMORY DEVICE AND RELATED METHODS, AND COMPUTER PROGRAM PRODUCTS THEREOF

(71) Applicant: Earth Top International Enterprises Ltd., Tortola (VG)

(72) Inventors: TSAI-CHUNG YU, Taipei (TW); NAN-HUEI LEE, Taipei (TW)

(21) Appl. No.: 18/829,587

(22) Filed: Sep. 10, 2024

Related U.S. Application Data
(60) Provisional application No. 63/539,639, filed on Sep. 21, 2023.

(51) Int. Cl. G11C 8/10; G11C 8/18

(52) U.S. Cl. CPC G11C 8/10; G11C 8/18

(57) ABSTRACT

Provided is a non-volatile semiconductor memory device, including: column lines and row lines; a column decoder for generating a column strobe signal to activate a column line according to a column address signal; a row decoder for generating a row strobe signal to activate a row line according to a row address signal; and a memory array including non-volatile memory cells at junctions of the column lines and row lines respectively. The non-volatile memory cells are each coupled to one of the column lines via a column-enabling switch and to one of the row lines via at least one row-enabling switch. The column-enabling switch and row-enabling switch allow the activated column line and activated row line to enable the non-volatile memory cells according to the row strobe signal and column strobe signal respectively so that the enabled non-volatile memory cells operate in a programming, erasing or reading mode.

### CROSS-REFERENCE TO RELATED APPLICATIONS

This application claims priority to U.S. Provisional Patent Application No. 63/539,639 filed in U.S. on Sep. 21, 2023 the entire contents of which are hereby incorporated by reference.

### BACKGROUND OF THE INVENTION

### Field of the Invention

The present disclosure relates to a non-volatile semiconductor memory device, a system-on-chip (SoC) using the memory device and related methods, and computer program products thereof, and more particularly to a non-volatile semiconductor memory device comprising a memory array comprising novel non-volatile memory cells, a system-on-chip (SoC) using the memory device and related methods, and computer program products thereof.

### Description of the Prior Art

According to prior art, memory falls into two categories: random-access memory (RAM) and non-volatile memory (NVM). Data retained in RAM will be lost if power is off. By contrast, data retained in NVM will not be lost even if power is off. RAM includes two categories: static random-access memory (static RAM, or SRAM for short) and dynamic random-access memory (dynamic RAM, or DRAM for short). SRAM is faster, requires no memory refresh, and provides lower memory density with more cost, which is adapted to the cache memory in CPUs. DRAM requires memory refresh, and provides higher memory density with less cost, which is adapted to external memory removably connected to CPUs. NVM includes categories as follows: read-only memory (ROM), programmable read-only memory (PROM), erasable programmable read-only memory (EPROM), electrically erasable programmable read-only memory (EEPROM), and flash memory.

ROM cannot be programmed, and its data is determined during IC manufacturing. PROM is programmable for once only, and its data is then permanent and cannot be changed. EPROM is typically for use in storing system code, and achieves data erasing with ultraviolet (UV) light to allow 10,000 to 100,000 times of erasing by requiring the entire memory to be the minimum amount of data erased, and achieves data programming through hot electron injection by requiring the entire memory to be the minimum amount of data written. The minimum amount of data read is one byte.

EEPROM is typically for use in storing a small amount of parameter data, achieves data erasing through F-N tunneling to allow 1,000,000 times of erasing by requiring one byte to be the minimum amount of data erased, and achieves data programming through F-N tunneling by requiring one byte to be the minimum amount of data read/written. Flash memory is one type of EEPROM, which performs data erasing through F-N tunneling by requiring one block to be the minimum amount of data erased. NOR Flash allows 10,000 to 100,000 times of erasing. NAND Flash allows 100,000 to 1,000,000 times of erasing. Flash memory achieves data programming through hot electron injection. NOR Flash requires one byte to be the minimum amount of data read and one page to be the minimum amount of data written. NAND Flash requires one page to be the minimum amount of data read/written.

Referring to FIG. 1, there is shown a circuit diagram of a conventional non-volatile memory (NVM) device. The non-volatile memory (NVM) device comprises a column decoder 10, a row decoder 20, and a memory array 30 comprising a plurality of non-volatile memory cells (NVM cells) 31. FIG. 2 is a schematic view in which a non-volatile memory cell 31 in the memory array 30 is electrically connected to the junction of a column line and a row line.

The memory array 30 comprises one or more memory banks. In each memory bank, a plurality of non-volatile memory cells 31 are tightly arranged in rows and columns by being electrically connected to the junctions of a plurality of column lines 11 and a plurality of row lines 21 respectively. From the perspective of IC layout, the memory array is a neat, compact cubic block. Referring to FIG. 4, there is shown a circuit layout diagram of the conventional non-volatile memory (NVM) device shown in FIG. 1. In FIG. 4, the cubic block comprises therein the memory cells 31 only but not any other circuit components. A column decoder 10 electrically connected to a plurality of column lines of the cubic block is disposed in the vicinity of the cubic block, usually above (or below) the cubic block. A row decoder 20 electrically connected to a plurality of row lines of the cubic block is disposed on the left (or right) of the cubic block. The column decoder 10 and the row decoder 20 each comprise switches and multiplexers.

Referring to FIG. 1, the column decoder 10 generates a column strobe signal according to a column address signal to activate one of the plurality of column lines 11, and the row decoder 20 generates a row strobe signal according to a row address signal to activate one of the plurality of row lines 21. When the column decoder 10 and the row decoder 20 activate the column line 11 and the row line 21 according to the column address signal and the row address signal respectively, the non-volatile memory (NVM) device addresses one of the non-volatile memory cells 31 and uses a voltage source or current source 1 electrically connected to the column decoder 10 and the row decoder 20 to drive the column line 11 activated by the column decoder 10 and the row line 21 activated by the row decoder 20 respectively, enabling the addressed non-volatile memory cell 31 to operate in one of a programming mode, an erasing mode and a reading mode.

Take the voltage source 1 as an example, when the addressed non-volatile memory cell 31 is enabled to operate in different modes, the voltage source 1 electrically connected to the column decoder 10 and the row decoder 20 provides operating voltages required for different modes to the activated column line 11 and the activated row line 21 respectively, enabling the addressed non-volatile memory cell 31 to operate in one of a programming mode, an erasing mode and a reading mode.

A non-volatile memory cell is usually expressed by a combination of a capacitor and a MOSFET. Referring to FIG. 3A and FIG. 3B, there are shown two circuit diagrams of a non-volatile memory cell 31, expressed with circuit symbols. As shown in FIG. 3A and FIG. 3B, a non-volatile memory cell 31 has a drain (D) electrically connected to one column line and has a gate (G) and a source(S) electrically connected to two row lines. The activated column line and the activated row lines provide different operating voltages, enabling the addressed non-volatile memory cell 31 to operate in one of a programming mode, an erasing mode and a reading mode.

Referring to FIG. 5, there is shown a circuit structure diagram in which a portion of the memory array 30 addresses a non-volatile memory cell 31. Take driving and addressing by a voltage source in a conventional circuit framework as an example, when a column address signal addresses a non-volatile memory cell 31 of one of the column arrays of the memory array 30, the column decoder generates a column strobe signal according to the column address signal to activate one of the plurality of column lines 11. The voltage source provides operating voltage VDa to the activated column line 11 to allow all the drains of the non-volatile memory cell 31 of the addressed column arrays to receive the operating voltage VDa. The voltage source provides voltage VDb to the other unactivated column lines to allow all the drains of the non-volatile memory cell 31 of the other unaddressed column arrays to receive the voltage VDb.

When a row address signal addresses a non-volatile memory cell 31 of one of the row arrays of the memory array 30, the row decoder generates a row strobe signal according to a row address signal to activate two of the plurality of row lines 21. The voltage source provides operating voltages VGa and VSa to the two activated row lines 21 respectively and provides voltages VGb and VSb to the other unactivated row lines respectively. Therefore, all the gates and sources of the non-volatile memory cells 31 of the addressed row array receive the operating voltages VGa and Vsa respectively, and all the gates and sources of the non-volatile memory cells 31 of the other unaddressed row arrays receive voltages VGb and VSb provided by the other unactivated row lines respectively

Therefore, as shown in FIG. 5, the plurality of non-volatile memory cells 31 of a portion of the memory array 30 have four states (State 1, State 2, State 3, and State 4). The non-volatile memory cell 31 addressed by the activated column line 11 and the activated row lines 21 have State 1. The non-volatile memory cell 31 in State 1 receives operating voltages VDa, VGa and VSa. The voltage source provides the required operating voltages VDa, VGa and VSa according to the modes in which the operating non-volatile memory cells operate respectively. The non-volatile memory cells 31 addressed by the activated column line 11 and the unactivated row lines 21 have State 2. The non-volatile memory cells 31 in State 2 receive operating voltage VDa and voltages VGb and VSb. The non-volatile memory cells 31 addressed by the activated row lines 21 and the unactivated column line 11 have State 3. The non-volatile memory cells 31 in State 3 receive operating voltages VGa and VSa and voltage VDb. The non-volatile memory cells 31 addressed by the other unactivated column lines 11 and unactivated row lines 21 have State 4. The non-volatile memory cells 31 in State 4 receive voltages VGb, VSb and VDb.

Since the conventional memory array 30 uses the circuit framework shown in FIG. 1, the conventional non-volatile memory (NVM) device selects the required operating non-volatile memory cell 31 through the column line 11 activated by the column decoder and the row lines 21 activated by the row decoder 20. According to the prior art, the voltage or current for controlling the reading, writing or erasing of the operating non-volatile memory cell 31 is provided by the voltage source or current source 1 to the entire activated column line 11 via the column decoder 10 and influence the non-operating non-volatile memory cells 31 (State 2) of the entire column array, and provided by the voltage source or current source 1 to the entire activated row line 21 via the row decoder 20 and influence the non-operating non-volatile memory cells 31 (State 3) of the entire row array. Therefore, the addressing technique of the conventional non-volatile memory (NVM) device causes reading interference or writing interference to the nearby non-operating non-volatile memory cells 31 (States 2, 3), which may probably destroy the data stored in the nearby non-operating non-volatile memory cells 31, reducing the reliability of the operation of the memory array 30.

Possible interferences are described below for an exemplary purpose. Referring to FIG. 6A, there is shown a schematic view of the operation states of a portion of the memory array 30 having a conventional circuit framework and programming an operating non-volatile memory cell 31 through hot electron injection. The drain of an operating non-volatile memory cell 31 receives programming operating voltage VPb, while the gate and the source of the operating non-volatile memory cell 31 receive programming operating voltage VPa and 0V respectively, so as for the operating non-volatile memory cell 31 to operate in a programming mode. At this time, the unactivated column line and row lines provide 0V. The programming operating voltage VPb is likely to cause erasing interference to the nearby non-volatile memory cell 31 in State 2. The programming operating voltage VPa is likely to cause programming interference to the nearby non-volatile memory cell 31 in State 3.

Referring to FIG. 6B, there is shown a schematic view of the operation states of a portion of the memory array 30 having the conventional circuit framework and erasing an operating non-volatile memory cell 31 through F-N tunneling. The drain of an operating non-volatile memory cell 31 receives erasing operating voltage VEb, while the gate and the source of the operating non-volatile memory cell 31 receive 0V and erasing operating voltage VEa respectively, so as for the operating non-volatile memory cell 31 to operate in an erasing mode. At this time, the unactivated column line is potential-floating, while the unactivated row lines provide erasing operating voltage VEc. Erasing operating voltage VEb is likely to cause erasing interference to the nearby non-volatile memory cell 31 in State 2. Likewise, erasing operating voltage VEc is likely to cause programming interference to the nearby non-volatile memory cells 31 in State 2 and State 4. Furthermore, the potential-floating of the unactivated column lines and erasing operating voltage VEa are likely to cause erasing interference to the nearby non-volatile memory cell 31 in State 3.

Referring to FIG. 6C, there is shown a schematic view of the operation states of a portion of the memory array 30 having the conventional circuit framework and reading an operating non-volatile memory cell 31. The drain of an operating non-volatile memory cell 31 receives reading operating voltage VRb, while the gate and the source of the operating non-volatile memory cell 31 receive reading operating voltage VRa and 0V respectively, so as for the operating non-volatile memory cell 31 to operate in a reading mode. At this time, the unactivated column line and row lines provide 0V. Reading operating voltages VRb, VRa are likely to cause programming interference to other operating non-volatile memory cells 31. Reading operating voltage VRb is likely to cause erasing interference to the nearby non-volatile memory cell 31 in State 2. Reading operating voltage VRa is likely to cause programming interference to the nearby non-volatile memory cell 31 in State 3.

With the conventional circuit framework, the operation of the operating non-volatile memory cells in a specific mode is likely to cause erasing interference or programming interference to the nearby non-volatile memory cells 31 in the long term, reducing the reliability of the operation of the memory array 30.

Referring to FIG. 7, there is shown a schematic view of addressing a cell group 32 of a portion of the memory array 30 of FIG. 5. A plurality of non-volatile memory cells 31 of each group 32 are not only tightly arranged in rows and columns by being electrically connected to the junctions of a plurality of column lines and a plurality of row lines respectively but also addressed by an activated column line and an activated row line. Take driving and addressing by a voltage source in a conventional circuit framework as an example, addressing a cell group Group 1 of the memory array 30 with a column address signal and a row address signal results in the column decoder activating a column line to provide operating voltage VDa and the unactivated column lines providing voltage VDb as well as the row decoder activating two row lines to provide operating voltages VGa and VSa and the unactivated row lines providing voltages VGb and VSb. Thus, the non-volatile memory cells 30 in cell group Group 1 have State 1, in cell group Group 2 have State 2, in cell group Group 3 have State 3, and in cell group Group 4 have State 4.

With the circuit framework shown in FIG. 7, the conventional non-volatile memory (NVM) device selects the required operating memory cell group Group1 through the column line activated by the column decoder and the row lines activated by the row decoder. According to the prior art, the voltage or current for controlling the reading, writing or erasing of the operating memory cell group Group1 is provided by a voltage source or current source to the entire activated column line via the column decoder to the detriment of the memory cell group Group 2 and provided by the voltage source or current source to the entire activated row line via the row decoder to the detriment of the memory cell group Group 3. Therefore, the addressing technique of the conventional non-volatile memory (NVM) device causes programming interference or erasing interference to the nearby non-volatile memory cell groups (Groups 2 and 3), which may probably destroy the data stored in the nearby non-volatile memory cells, reducing the reliability of the operation of the memory array 30.

### SUMMARY OF THE INVENTION

Since the circuit framework used by the conventional non-volatile memory (NVM) device is likely to destroy the data stored in nearby non-volatile memory cells and thus reduce the reliability of the operation of the memory array, it is an objective of the disclosure to provide a novel non-volatile memory cell and a circuit framework comprising the novel non-volatile memory cells to form the memory array such that, in the memory array, unaddressed and non-operating non-volatile memory cells or cell groups remain unaffected by interference from addressed and operating non-volatile memory cells or cell groups, enhancing the reliability of the stable operation of the memory array.

Another objective of the disclosure is to provide a novel non-volatile memory device and a system-on-chip comprising the novel non-volatile memory device such that, in the memory array of the non-volatile memory device, unaddressed and non-operating non-volatile memory cells or cell groups remain unaffected by interference from addressed and operating non-volatile memory cells or cell groups, enhancing the reliability of the stable operation of the non-volatile memory device.

Yet another objective of the disclosure is to provide a novel addressing method and a memory control method using the novel addressing method such that, in a non-volatile memory (NVM) device comprising novel non-volatile memory cells, unaddressed and non-operating non-volatile memory cells or cell groups remain unaffected by interference from addressed and operating non-volatile memory cells or cell groups, enhancing the reliability of the stable operation of the memory array.

Still yet another objective of the disclosure is to provide a novel addressing method and a method of operating a non-volatile memory device with the novel addressing method to allow the non-volatile memory device to use the novel addressing method in addressing and operating non-volatile memory cells or cell groups to operate in one of a programming mode, an erasing mode and a reading mode without interfering with the unaddressed and non-operating non-volatile memory cells or cell groups so as to enhance the reliability of the stable operation of the non-volatile memory device.

A further objective of the disclosure is to provide a memory array layout method that involves using a column-segment line and a row-segment line to define each memory block of a memory array such that the unaddressed and non-operating memory blocks in the memory array are free of interference from the addressed and operating memory blocks in the memory array, enhancing the reliability of the stable operation of the memory array.

To achieve the above and other objectives, the disclosure provides a non-volatile semiconductor memory device, comprising: a plurality of row lines; a plurality of column lines; a column decoder for generating a column strobe signal to activate a column line according to a column address signal; a row decoder for generating a row strobe signal to activate a row line according to a row address signal; and a memory array comprising a plurality of non-volatile memory cells built around junctions of the column lines and the row lines respectively, wherein the non-volatile memory cells are each coupled to one of the plurality of column lines via a column-enabling switch and coupled to one of the plurality of row lines via at least one row-enabling switch, the column-enabling switch allows the activated column line to enable the non-volatile memory cells according to the row strobe signal, and the row-enabling switch allows the activated row line to enable the non-volatile memory cells according to the column strobe signal, so as for the enabled non-volatile memory cells to operate in one of a programming mode, an erasing mode and a reading mode.

To achieve the above and other objectives, the disclosure further provides a system-on-chip comprising: the non-volatile semiconductor memory device; and a power source circuit electrically connected to the row decoder and the column decoder to provide a voltage required for the enabled non-volatile memory cells to operate in each of the modes.

To achieve the above and other objectives, the disclosure further provides an addressing method, for addressing at least one of a plurality of non-volatile memory cells (NVM cells), the plurality of non-volatile memory cells each corresponding to at least one column line and corresponding to at least one row line, the addressing method comprising the steps of: generating a column strobe signal according to a column address signal to activate a column line; generating a row strobe signal according to a row address signal to activate a row line; enabling, by the column line, the at least one non-volatile memory cell according to the row strobe signal; and enabling, by the row line, the at least one non-volatile memory cell according to the column strobe signal, allowing the at least one non-volatile memory cell to operate in one of a programming mode, an erasing mode and a reading mode.

To achieve the above and other objectives, the disclosure further provides a method of operating a non-volatile semiconductor memory device, with the non-volatile semiconductor memory device comprising a plurality of non-volatile memory cells, the method comprising the steps of: addressing at least one non-volatile memory cell with the addressing method; and operating the at least one non-volatile memory cell to program and write digital data, to erase stored digital data, or to read stored digital data.

To achieve the above and other objectives, the disclosure further provides a non-volatile semiconductor memory device, comprising: a column decoder configured for generating a column strobe signal according to a column address signal to activate one of a plurality of column lines; a row decoder configured for generating a row strobe signal according to a row address signal to activated one of a plurality of row lines; and a memory array comprising a plurality of non-volatile memory cells divided into a plurality of memory blocks, wherein each of the non-volatile memory cells in each of the memory blocks is electrically connected to a column-segment line and a row-segment line, and each of the memory blocks comprises a column-enabling switch array and a row-enabling switch array, the column-enabling switch array allows a part of the column lines to electrically connect to the column-segment lines of the memory blocks according to the row strobe signal, and the row-enabling switch array allows a part of the row lines to electrically connect to the row-segment lines of the memory blocks according to the column strobe signal. One of the memory blocks is enabled according to the column strobe signal and the row strobe signal, and at least one non-volatile memory cell of the memory block is enabled according to the column line activated by the column strobe signal and the row line activated by the row strobe signal to operate in one of a programming mode, an erasing mode and a reading mode.

To achieve the above and other objectives, the disclosure further provides a memory array layout method, comprising the steps of: arranging a plurality of column lines and a plurality of row lines of a metal layer; and defining a plurality of memory blocks on a component layer, the memory blocks each providing a plurality of non-volatile memory cells (NVM cells) each corresponding in position to one column line and one row line; wherein a plurality of column-segment lines and a plurality of row-segment lines are provided within the metal layer and correspond in position to the memory blocks respectively, and each of the non-volatile memory cells of the memory blocks are electrically connected to a corresponding column-segment line and a corresponding row-segment lines; wherein at least one column-enabling switch array and/or at least one row-enabling switch array is disposed within the component layer and between two adjacent ones of the memory blocks, wherein the column-enabling switch array controllably causes a part of the column lines to electrically connect to the column-segment lines of the memory blocks respectively, and the row-enabling switch array controllably causes a part of the row lines to electrically connect to the row-segment lines of the memory blocks.

To achieve the above and other objectives, the disclosure further provides a memory control method, for controlling a memory array with the layout method, the memory control method comprising the steps of: controlling the column-enabling switch array to cause a part of the column lines to electrically connect to the column-segment lines of the memory blocks according to the row strobe signal; and controlling the row-enabling switch array to cause a part of the row lines to electrically connect to the row-segment lines of the memory blocks according to the column strobe signal.

The disclosure provides a non-volatile memory device for implementing novel non-volatile memory cells, a system-on-chip using the memory device and its novel addressing method, and a memory control method such that, in a memory array comprising the novel non-volatile memory cells, the unaddressed and non-operating non-volatile memory cells or cell groups remain unaffected by interference from the addressed and operating non-volatile memory cells or cell groups, enhancing the reliability of the stable operation of the memory array.

### BRIEF DESCRIPTION OF THE DRAWINGS

FIG. 1 (PRIOR ART) is a circuit diagram of a conventional non-volatile memory (NVM) device.

FIG. 2 (PRIOR ART) is a schematic view in which a non-volatile memory cell is electrically connected to a column line and a row line.

FIG. 3A (PRIOR ART) is a circuit diagram of a non-volatile memory cell, expressed with circuit symbols.

FIG. 3B (PRIOR ART) is another circuit diagram of a non-volatile memory cell, expressed with circuit symbols.

FIG. 4 (PRIOR ART) is a circuit layout diagram of the conventional non-volatile memory (NVM) device shown in FIG. 1.

FIG. 5 (PRIOR ART) is a circuit structure diagram in which a portion of a memory array addresses a non-volatile memory cell.

FIG. 6A (PRIOR ART) is a schematic view of the operation state of a portion of the memory array performing programming through hot electron injection.

FIG. 6B (PRIOR ART) is a schematic view of the operation state of a portion of the memory array performing erasing through F-N tunneling.

FIG. 6C (PRIOR ART) is a schematic view of the operation state of a portion of the memory array performing reading.

FIG. 7 (PRIOR ART) is a schematic view of a portion of the memory array addressing a cell group.

FIG. 8A is a schematic view of a non-volatile memory cell of the disclosure.

FIG. 8B is a circuit diagram of a non-volatile memory cell of the disclosure.

FIG. 9 is a circuit structure diagram of an addressing mode of the memory array of the disclosure.

FIG. 10A is a schematic view of a non-volatile memory cell/group in an operation state according to the disclosure.

FIG. 10B is a schematic view of a non-volatile memory cell/group in a non-operation state according to the disclosure.

FIG. 11 is a circuit structure diagram of another addressing mode of the memory array of the disclosure.

FIG. 12 is a circuit layout diagram of a non-volatile memory (NVM) device of the disclosure.

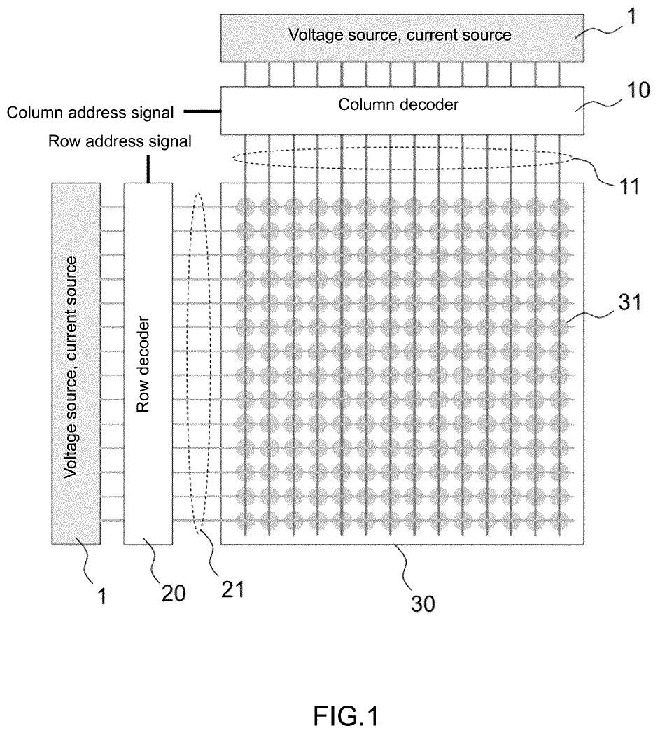

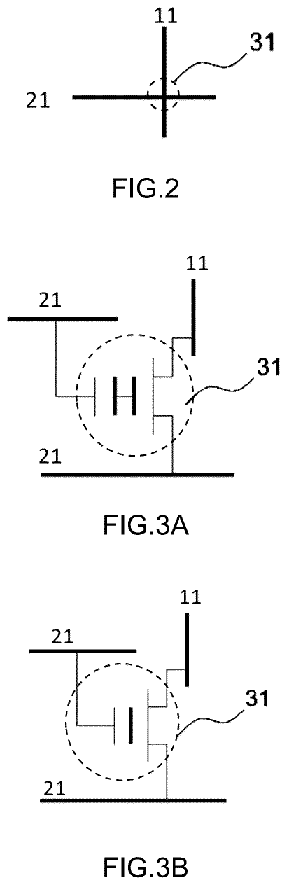

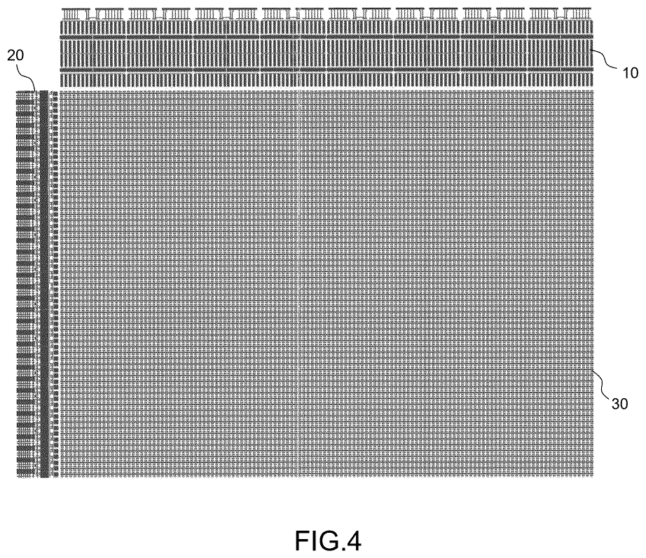

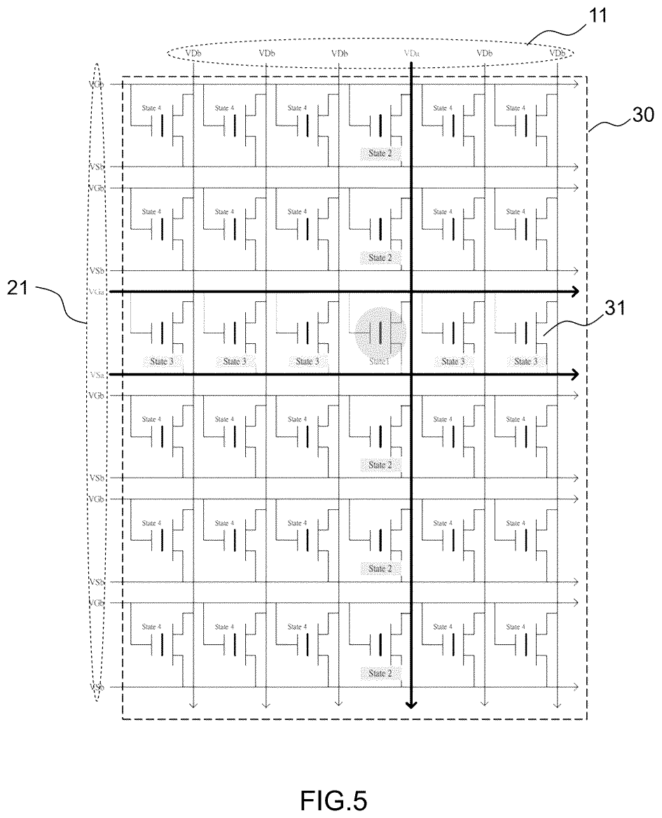

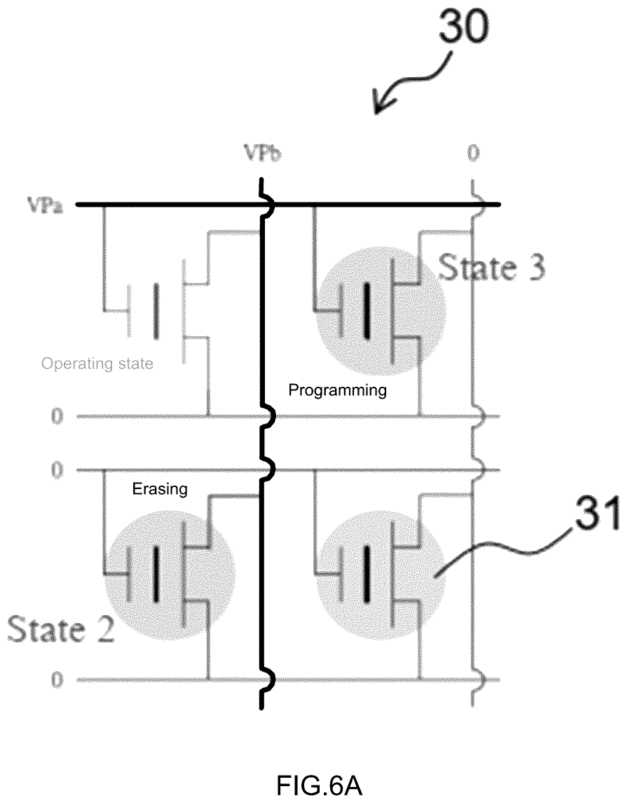

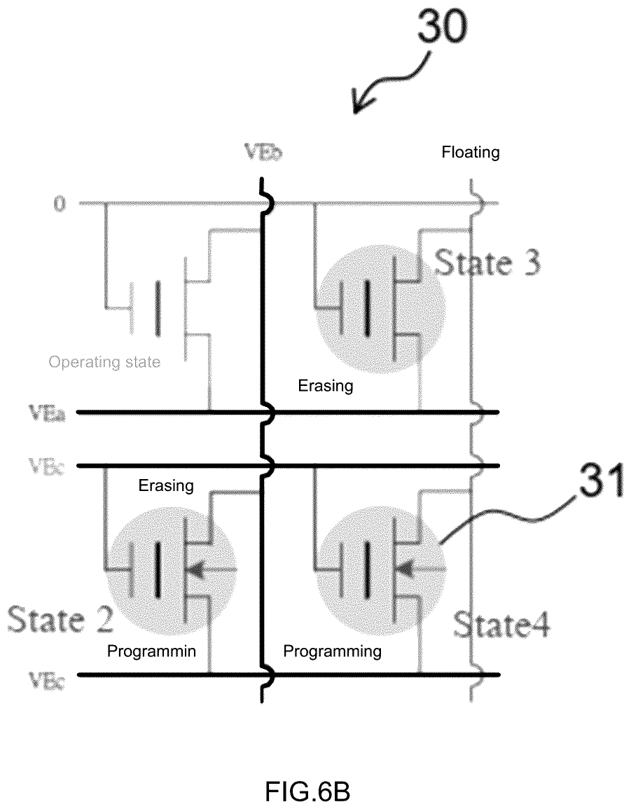

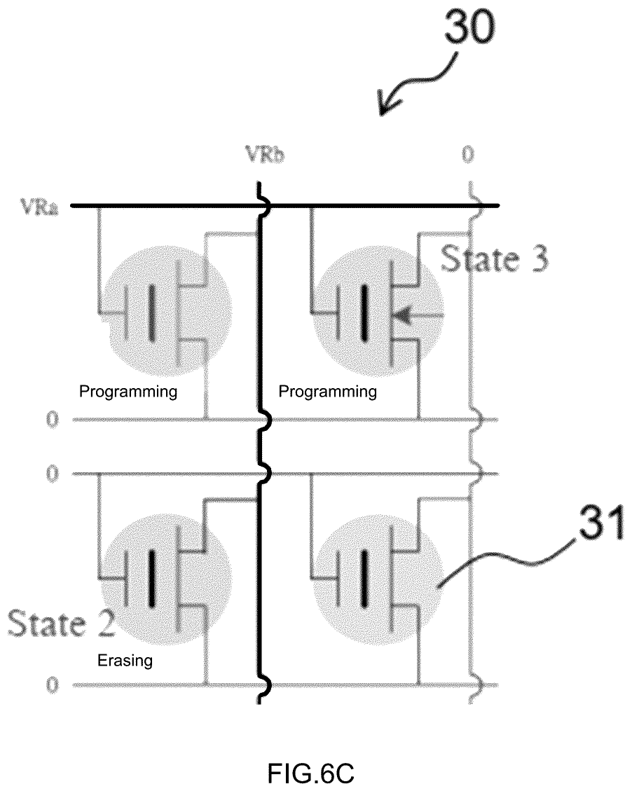

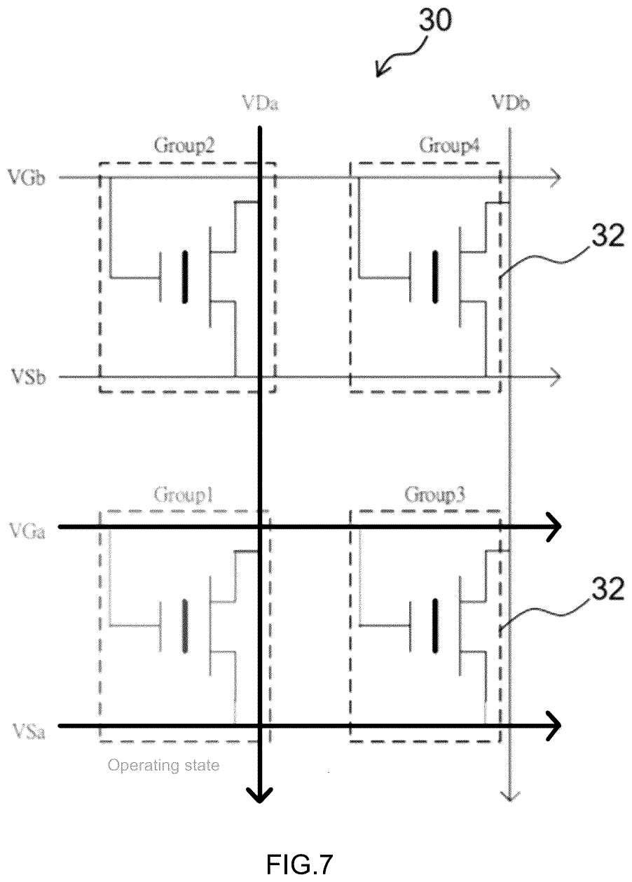

### DETAILED DESCRIPTION OF THE EMBODIMENTS

The definitions for all technical and scientific terms used herein are the same as the meanings usually understood by persons skilled in the art. The technical terms explained herein are merely aimed at describing basic definitions instead of limiting the scope of the claims of the disclosure. The expression “and/or” used herein indicates any combinations and all combinations of one or more related specified items.

Definition of the word “couple”: to physically connect via at least one device, or physically connect not via any device. For example, both “device A is physically connected to device B via device C” and “device A is physically connected to device B” are regarded as “device A is coupled to device B.”

Definition of the word “electrically connection”: electrical connection capable of transferring electrical energy, or electrical connection capable of transferring electrical energy via at least one device. For example, both “a power source is electrically connected to device A by a conductor” and “a power source is electrically connected to device A by a conductor via an electronic switch” are regarded as “the power source is electrically connected to device A.”

Definition of the word “enable”: to cause a device to be able to perform a specific function. For example, “a column strobe signal activates a column line, and a row strobe signal activates a row line, allowing a non-volatile memory cell to which the column line and the row line are connected to operate in a programming mode, an erasing mode and a reading mode” is regarded as “a column strobe signal or a row strobe signal enables the non-volatile memory cell,” or “an activated column line or an activated row line enables the non-volatile memory cell.”

The disclosure is depicted by accompanying drawings, illustrated by specific embodiment of specific examples, and described in detail below. However, the disclosure can be implemented in various ways; hence, the construction of the claims of the disclosure or the scope thereof is not restricted to the specific embodiments of any examples disclosed herein. The specific embodiments of the examples serve illustrative purposes only. Furthermore, the disclosure can be specifically implemented by a method, circuit, device or system, or computer program products. Therefore, the specific embodiments can be provided, for example, in the form of hardware, software, firmware or any combinations thereof.

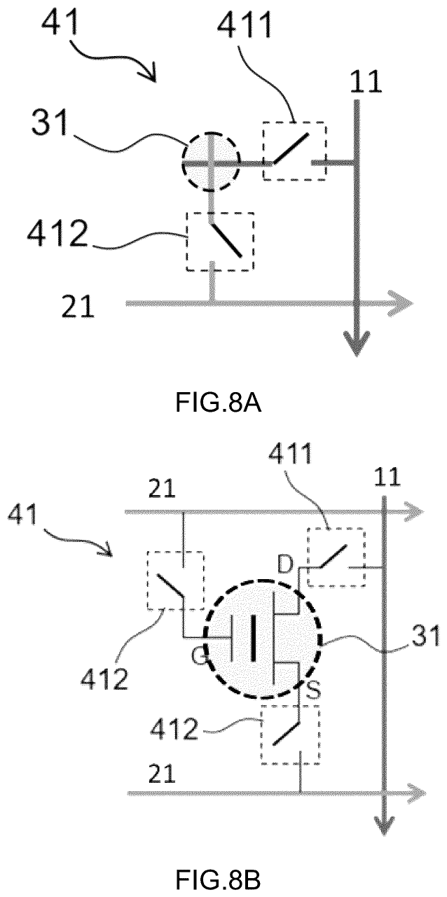

Referring to FIG. 8A and FIG. 8B, there are shown a schematic view and a circuit diagram of a novel non-volatile memory cell of the disclosure respectively. According to the disclosure, a novel non-volatile memory cell 41 comprises a non-volatile memory cell 31, at least one column-enabling switch 411 and at least one row-enabling switch 412 and is adapted to be built around a junction of a column line and a row line of a memory array. The column line is physically connected to the non-volatile memory cell 31 via the column-enabling switch 411, and the row line is physically connected to the non-volatile memory cell 31 via the row-enabling switch 412; thus, activating the column line and the row line enables the non-volatile memory cell 31 to operate in one of a programming mode, an erasing mode and a reading mode.

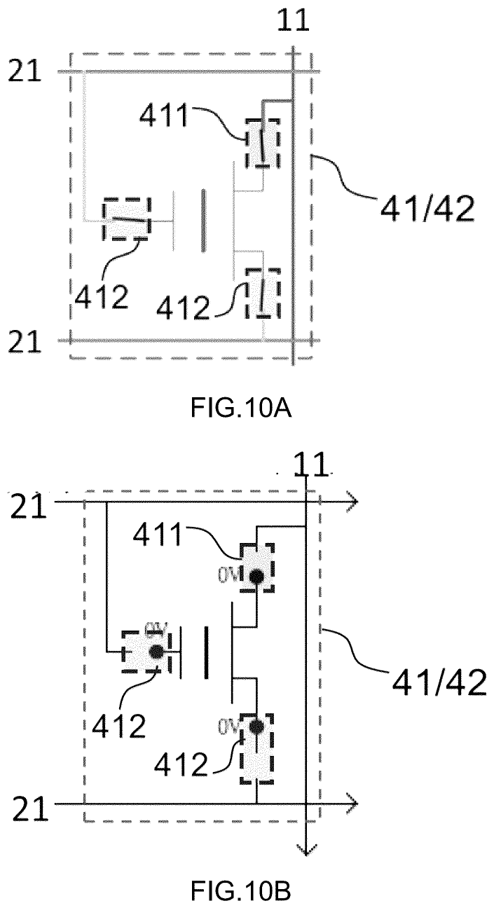

Referring to FIG. 8B, in an embodiment of the disclosure, a novel non-volatile memory cell 41 is adapted to be disposed at the junctions of a column line and two row lines in a memory array and comprises a column-enabling switch 411, two row-enabling switches 412 and a floating gate MOSFET (also known as FGMOS) 31. The drain of the FGMOS 31 is coupled to the column line via the column-enabling switch 411. The gate and source of the FGMOS 31 are coupled to the two row lines via the two row-enabling switches 412 respectively. When the column line and the two row lines are activated, the column-enabling switch 411 and the two row-enabling switches 412 turn ON, as shown in FIG. 10A; thus, the column line and the two row lines are electrically connected to the FGMOS 31 and provide the electric power required for the FGMOS 31 to enable the FGMOS 31 to enter an operating state and operate in one of a programming mode, an erasing mode and a reading mode.

Upon completion of the operation of the FGMOS 31 in one of the modes, the electric potential of the activated column line and the two activated row lines drops to 0V, and then the column-enabling switch 411 and the two row-enabling switches 412 turn OFF, as shown in FIG. 10B; thus, the gate, source and drain of the FGMOS 31 stay at 0V and enter a non-operating state. Therefore, according to the disclosure, with the novel non-volatile memory cells being in the non-operating state, the electric potentials at the gate, source and drain of the FGMOS 31 are free of interference regardless of whether the column line and the two row lines are activated, so as to enhance the reliability of the stable operation of the memory array.

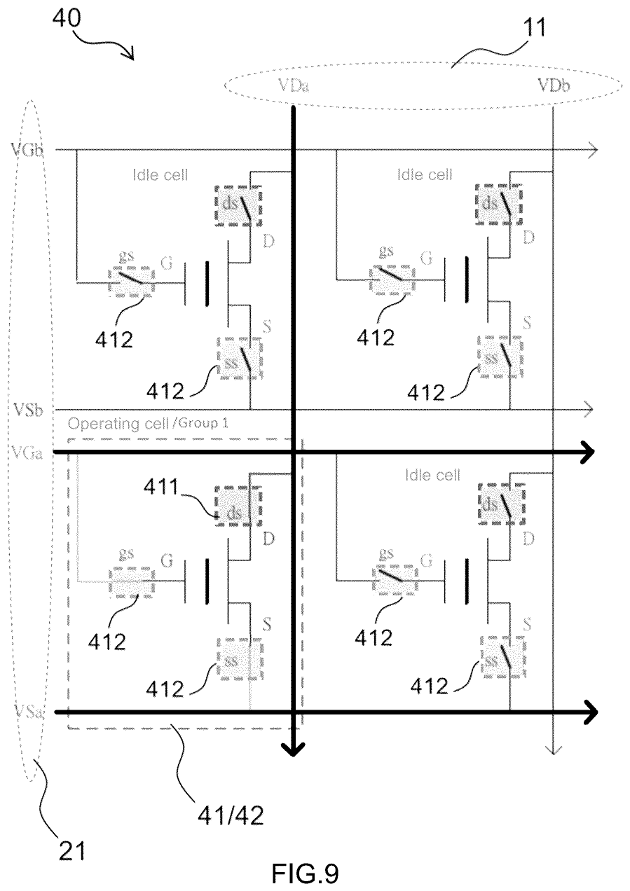

Referring to FIG. 9, there is shown a circuit structure diagram of an addressing mode of the memory array of the disclosure. In another embodiment of the disclosure, a memory array 40 comprises: a plurality of column lines 11 parallel to each other; a plurality of row lines 21 parallel to each other; and a plurality of novel non-volatile memory cells 41 each disposed at the junction of one of the column lines 11 and at least one of the row lines 21 and each comprises a column-enabling switch 411, at least one row-enabling switch 412 and a non-volatile memory cell. The non-volatile memory cell is not only coupled to the column line 11 via the column-enabling switch 411 but also coupled to the at least one row line 21 via the row-enabling switch 412.

The non-volatile memory cells are explained in terms of FGMOS implementation for exemplified purposes. The FGMOS is disposed at the junctions of a column line 11 and two row lines 21 in the memory array 40. The drain of the FGMOS is coupled to the column line 11 via the column-enabling switch 411. The gate and source of the FGMOS are coupled to two row lines 21 via the two row-enabling switches 412 respectively. The column-enabling switch 411 and the two row-enabling switches 412 are controllably turned ON or turned OFF to allow the activated column line 11 and activated row lines 21 to be electrically connected to the FGMOS to enable the FGMOS to enter an operating state and operate in one of a programming mode, an erasing mode and a reading mode.

When the column line 11 and the at least one row line 21 are activated to address the non-volatile memory cells, the column-enabling switch 411 and the at least one row-enabling switch 412 are turned ON to allow the activated column line 11 and the activated row lines 21 to electrically connect to the addressed non-volatile memory cell and provide the electric power required for the non-volatile memory cell to enable the non-volatile memory cell to enter an operating state and operate in one of a programming mode, an erasing mode and a reading mode.

Upon completion of the operation of the non-volatile memory cell in a specific mode, the electric potential of the activated column line 11 and the activated row lines 21 decreases to 0V, and then the column-enabling switch 411 and the row-enabling switch 412 are turned OFF to allow the non-volatile memory cell to be electrically isolated and enter a non-operating state. Therefore, according to the disclosure, when the non-volatile memory cell of the memory array 40 is unaddressed and in a non-operating state, the column-enabling switch 411 and the row-enabling switch 412 are turned OFF and thus is not electrically connected to the corresponding column line 11 and the corresponding row line 21, so that the unaddressed non-volatile memory cell is electrically isolated and thus enters an idle state. The idle non-volatile memory cell does not receive any voltage and thus are free of interference from the mode in which other operating cells are operating. Therefore, the reliability of the stable operation of the memory array 40 is ensured.

Referring to FIG. 9, in yet another embodiment of the disclosure, a memory array comprises: a plurality of column lines 11 parallel to each other; a plurality of row lines 21 parallel to each other; and a plurality of novel non-volatile memory cells 41 divided into a plurality of non-volatile memory cell groups 42 each disposed at the junction of a corresponding one of the column lines 11 and at least one row line 21. The non-volatile memory cell group 42 is coupled to the column line 11 via at least one column-enabling switch 411 and coupled to the at least one row line 21 via the row-enabling switch 412. When the column line 11 and the at least one row line 21 are activated to address the non-volatile memory cell group 42, both the column-enabling switch 411 and the at least one row-enabling switch 412 turn ON; thus, the activated column line 11 and the activated row lines 21 are electrically connected to the addressed non-volatile memory cell group 42, and the one or more non-volatile memory cells 41 of the addressed non-volatile memory cell group 42 also enter an operating state and operates in one of a programming mode, an erasing mode and a reading mode.

When the non-volatile memory cell group 42 is configured to have the non-volatile memory cells 41 which form one byte or one character, the non-volatile memory cell group 42 which have entered an operating state can operate in the programming mode, erasing mode or reading mode of one byte or one character. The non-volatile memory cells which form one byte or one character are described in terms of FGMOS implementation for exemplified purposes. The FGMOS drains are connected to each other and coupled to a column line 11 via the column-enabling switches 411. The FGMOS gates are connected to each other and coupled to a row line 21 via the row-enabling switches 412. The FGMOS sources are connected to each other and coupled to another row line 21 via the row-enabling switches 412. Therefore, all the memory cells of the FGMOS for one byte or one character can simultaneously operate in the programming mode, erasing mode or reading mode.

Referring to FIG. 9, the non-volatile memory cells are not only described in terms of FGMOS implementation but also driven and addressed by a voltage source, for exemplified purposes. When a column address signal and a row address signal together address a FGMOS of the memory array 40, a column decoder generates a column strobe signal to activate a column line 11 according to the column address signal, while a row decoder generates a row strobe signal to activate a row line 21 according to the row address signal. The row strobe signal controllably causes the column-enabling switch 411 to turn ON, and the column strobe signal controllably causes the row-enabling switch 412 to turn ON; thus, the activated column line 11 provides operating voltage VDa to the drain of the FGMOS addressed, and the activated row line 21 provides operating voltages VGa and VSa to the gate and source of the FGMOS addressed respectively. At this time, the unactivated column lines 11 provide voltage VDb, and the unactivated row lines 21 provide voltages VGb and VSb. Therefore, the addressed FGMOS can operate in the programming mode, erasing mode or reading mode. Since the column strobe signal and the row strobe signal do not controllably cause the column-enabling switch 411 and the row-enabling switch 412 to turn ON, the unaddressed FGMOS is electrically isolated and enters an idle state, such that the unaddressed FGMOS is free of interference from the mode in which the other operating cells 41 or groups 42 are operating.

Therefore, the unaddressed non-volatile memory cells 41 or non-volatile memory cell groups 42 in the memory array 40 do not enter an operating state. At this time, the unactivated column line 11 provide voltage VDb, while the unactivated row lines 21 provide voltages VGb and VSb; however, the other column-enabling switches 411 and the row-enabling switches 412 are not turned ON such that the non-volatile memory cells 41 or non-volatile memory cell groups 42 which do not enter an operating state are free of interference from other voltages provided to the activated or unactivated column lines 11 and the activated or unactivated row lines 21.

In an embodiment of the disclosure, a non-volatile memory (NVM) device comprises a memory array 40. The memory array 40 comprises a plurality of row lines 21, a plurality of column lines 11 and a plurality of non-volatile memory cells (NVM cells) each built around the junction of a corresponding one of the column lines 11 and a corresponding one of the row lines 21. The non-volatile memory (NVM) device further comprises a column decoder and a row decoder. The column decoder generates a column strobe signal to activate a column line according to a column address signal. The row decoder generates a row strobe signal to activate a row line according to a row address signal. The activated column line and the activated row line provide the operating voltage required for the operation of the addressed non-volatile memory cell in each of the modes.

In the memory array 40 of the disclosure, each non-volatile memory cell is coupled to a corresponding one of the column lines 11 via a column-enabling switch 411 and coupled to a corresponding one of the row lines 21 via at least one row-enabling switch 412. As shown in FIG. 9, the non-volatile memory cells are described in terms of FGMOS for exemplified purposes. The FGMOS drains are coupled to a corresponding one of the column lines 11 via a column-enabling switches 411. The FGMOS gates and sources are coupled to a corresponding one of the row lines 21 via two row-enabling switches 412 respectively. The row strobe signal controllably causes the column-enabling switch 411 to turn ON such that the activated column line 11 electrically connects to the FGMOS drains, causing the activated column line 11 to electrically connect to the operating non-volatile memory cells only. The row strobe signal does not controllably cause the other column-enabling switches 411 to turn ON such that the activated column line 11 and the other unactivated column lines 11 do not electrically connect to the other non-operating non-volatile memory cells. The column strobe signal controllably causes the two row-enabling switches 412 to turn ON such that the two activated row lines 21 electrically connect to the FGMOS gates and sources respectively, causing the two activated row lines 21 to electrically connect to the operating non-volatile memory cells only. The column strobe signal does not controllably cause the other row-enabling switches 412 to turn ON, and thus the two activated row lines 21 and the other unactivated row lines 21 do not electrically connect to the other non-operating non-volatile memory cells. Therefore, when a column address signal and a row address signal together address a cell 41 or a group 42 of the memory array 40 of the disclosure, the activated column line 11 and the activated row lines 21 provide the operating voltage required for each mode, allowing the operating cell 41 or group 42 to operate in one of a programming mode, an erasing mode and a reading mode.

Upon completion of the operation of the operating memory cell, the electric potential of the activated column line 11 and the activated row lines 21 decreases to 0V from the operating voltage, which then controllably cause the column-enabling switch 411 and the row-enabling switches 412 to turn OFF, allowing the drain, gate and source of the memory cell to stay at 0V. Therefore, the non-operating cell 41 or group 42 of the memory array 40 of the disclosure are electrically isolated from the column lines 11 and row lines 21 and thus enters into an idle state.

In an embodiment of the disclosure, the disclosure provides a method of manufacturing a non-volatile memory (NVM) device, comprising the steps of: providing a column-enabling switch between each non-volatile memory cell and one of the column lines in a layout of the memory array; and providing at least one row-enabling switch between each non-volatile memory cell and at least one row line in the layout of the memory array. The non-volatile memory cells are exemplified by FGMOS and arranged as follows: a column-enabling switch is disposed between the drain of each FGMOS and one of the column lines in a layout of the memory array, whereas two row-enabling switches are disposed between the gate and source of each FGMOS and two corresponding row lines respectively in the layout of the memory array.

In an embodiment of the disclosure, an addressing method is performed by the non-volatile memory (NVM) device and aimed at addressing at least one of a plurality of non-volatile memory cells in a memory array, and each non-volatile memory cell in the memory array corresponds in position to at least one column line and corresponds in position to at least one row line. The addressing method of the disclosure comprises the steps of: generating, by a column decoder, a column strobe signal to activate a column line according to a column address signal; generating, by a row decoder, a row strobe signal to activate a row line according to a row address signal; controlling a column-enabling switch according to the row strobe signal to allow the activated column line to enable the at least one non-volatile memory cell; and controlling at least one row-enabling switch according to the column strobe signal to allow the activated row line to enable the at least one non-volatile memory cell, allowing the at least one non-volatile memory cell to operate in one of a programming mode, an erasing mode and a reading mode.

In an embodiment of the disclosure, the programming method for the non-volatile memory (NVM) device of the disclosure, together with the addressing method of the disclosure, addresses at least one non-volatile memory cell in a memory array to not only allow the addressed non-volatile memory cell to receive the operating voltage required to operate in the programming mode but also allow the unaddressed non-volatile memory cells to be electrically isolated from the corresponding column lines and row lines, so as to program the addressed non-volatile memory cell and write digital data. The erasing method for the non-volatile memory (NVM) device of the disclosure, together with the addressing method of the disclosure, addresses at least one non-volatile memory cell in a memory array to not only allow the addressed non-volatile memory cell to receive the operating voltage required to operate in the erasing mode but also allow the unaddressed non-volatile memory cells to be electrically isolated from the corresponding column lines and row lines, so as to erase digital data stored in the addressed non-volatile memory cell. The reading method for the non-volatile memory (NVM) device of the disclosure, together with the addressing method of the disclosure, addresses at least one non-volatile memory cell in a memory array to not only allow the addressed non-volatile memory cell to receive the operating voltage required to operate in the reading mode but also allow the unaddressed non-volatile memory cells to be electrically isolated from the corresponding column lines and row lines, so as to read digital data stored in the addressed non-volatile memory cell.

In an embodiment of the disclosure, a system-on-chip comprises: the non-volatile memory (NVM) device of the disclosure; and a power source circuit electrically connected to a column decoder and a row decoder of the non-volatile memory (NVM) device to provide voltage required for the enabled operating non-volatile memory cells or groups to operate in each mode.

In an embodiment of the disclosure, a memory control method, performed by the non-volatile memory (NVM) device of the disclosure and adapted for use with a memory controller, comprises the steps of: controllably causing at least one row-enabling switch to turn ON according to a column strobe signal generated by a column address signal to allow the addressed non-volatile memory cell to electrically connect to the activated row line; and controllably causing a column-enabling switch to turn ON according to a row strobe signal generated by a row address signal to allow the addressed non-volatile memory cell to electrically connect to the activated column line, allowing the column line activated by the column strobe signal and the row line activated by the row strobe signal to enable at least one non-volatile memory cell to operate in one of a programming mode, an erasing mode and a reading mode.

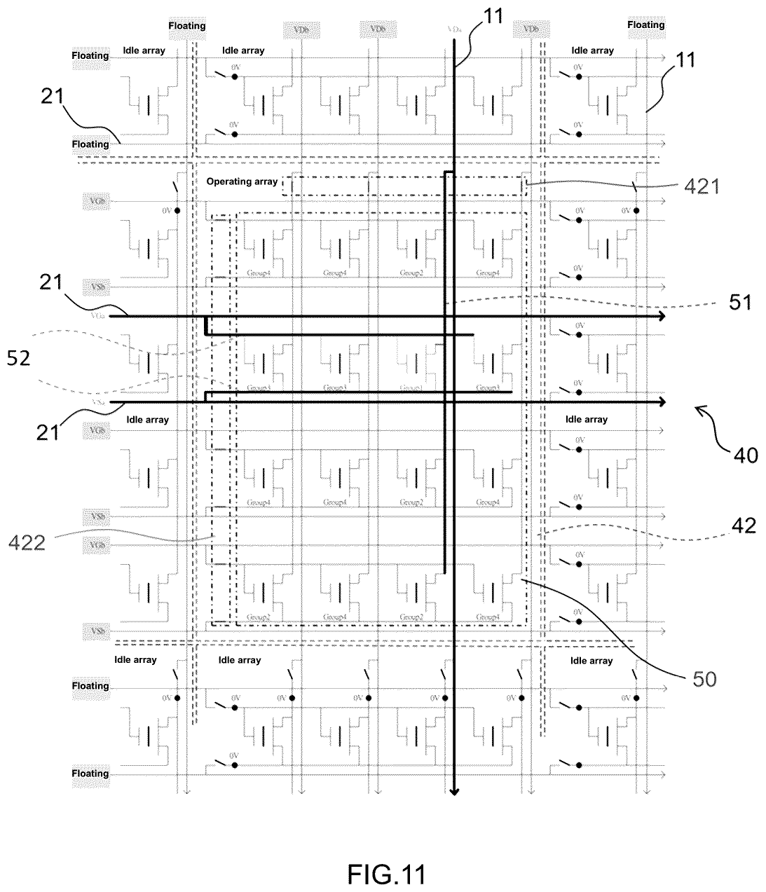

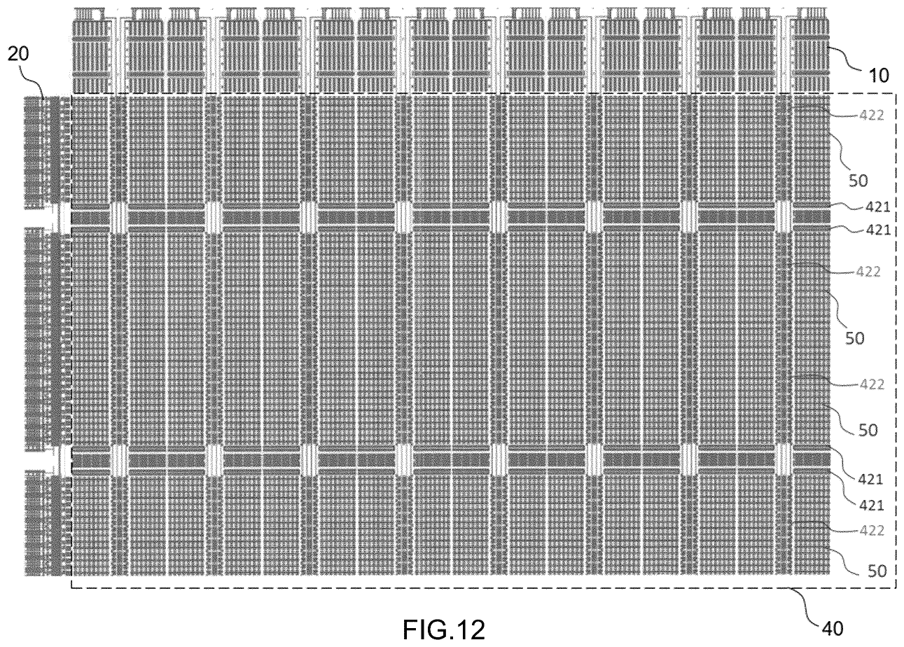

Referring to FIG. 11, there is shown another circuit structure diagram of the memory array 40 for addressing according to the invention. In this embodiment of the disclosure, the non-volatile memory cells are exemplified by FGMOS transistors. Since each FGMOS transistor has a column-enabling switch 411 and two row-enabling switches 412, the layout area of the memory array increases with the number of the enabling switches 411 and 412. Therefore, the reduction in the number of the enabling switches is conducive to the reduction in the layout area of the memory array or an increase in the number of the non-volatile memory cells so as to obtain cost-effectiveness.

In this embodiment of the disclosure, the memory array 40 comprises: a plurality of column lines 11 parallel to each other; a plurality of row lines 21 parallel to each other; and a plurality of non-volatile memory cells divided into a plurality of non-volatile memory cell groups 42. The non-volatile memory cell groups 42 each comprises a memory block 50, a column-enabling switch array 421 and a row-enabling switch array 422. Each memory block 50 comprises a plurality of column-segment lines 51, a plurality of row-segment lines 52 and a plurality of non-volatile memory cells, wherein the plurality of non-volatile memory cells of the memory block 50 are tightly arranged in rows and columns by being electrically connected to the junctions of the plurality of column-segment lines 51 and the plurality of row-segment lines 52 respectively.

Each memory block 50 has a column-enabling switch array 421 and a row-enabling switch array 422. From the perspective of IC layout, as shown in FIG. 12, the memory array 40 comprises a plurality of neat, compact cubic blocks corresponding in position to the memory blocks 50 of the non-volatile memory cell groups 42 respectively. The column-enabling switch array 421 is disposed above or below the cubic blocks, and the row-enabling switch array 422 is disposed on the left or right of the cubic blocks. The column-enabling switch array 421 comprises a plurality of column-enabling switches, and the column-segment lines 51 are coupled to the column lines 11 via the column-enabling switches respectively. The row-enabling switch array 422 comprises a plurality of row-enabling switches, and the row-segment lines 52 are coupled to the row lines 21 via the row-enabling switches respectively. When a column address signal and a row address signal together address one of the memory blocks 50 of the memory array 40, all the column-enabling switch array 421 and row-enabling switch array 422 of the operating memory block 50 turn ON such that all the column-segment lines 51 and all the row-segment lines 52 of the operating memory block 50 are electrically connected to the column lines 11 and the row lines 21 respectively so as to enable the addressed non-volatile memory cells in the operating memory block 50 to operate in one of a programming mode, an erasing mode and a reading mode.

The non-volatile memory cells are exemplified by FGMOS in the description below. Not all the non-volatile memory cells in the operating memory block 50 enter an operating state for reasons as follows: the activated column line 11 is only electrically connected to one column-segment line 51 of the operating memory block 50 to provide operating voltage VDa, while the unactivated column lines 11 are electrically connected to the other column-segment lines 51 of the operating memory block 50 to provide voltage VDb; and the activated row line 21 is only electrically connected to two row-segment lines 52 of the operating memory block 50 to provide operating voltages VGa and VSa, while the unactivated row lines 21 are electrically connected to the other row-segment lines 52 of the operating memory block 50 to provide voltages VGb and VSb. Therefore, in the memory block 50, only the non-volatile memory cells addressed by the activated column line 11 and the activated row line 21 can operate in one of a programming mode, an erasing mode and a reading mode.

In the memory array 40 of the disclosure, all the column-enabling switch arrays 421 and row-enabling switch arrays 422 of the other non-operating memory blocks 50 turn OFF such that none of the column-segment lines 51 and row-segment lines 52 of the other non-operating memory blocks 50 are electrically connected to corresponding ones of the column lines 11 and corresponding ones of the row lines 21. Thus, all the non-volatile memory cells of the other non-operating memory blocks 50 enter an idle state. The idle non-volatile memory cells do not receive any voltage and thus are free of interference from the mode in which other operating memory blocks 50 are operating.

According to the disclosure, the column decoder and the row decoder of a non-volatile memory (NVM) device in the embodiment illustrated by FIG. 11 are the same as their counterparts in the other embodiments. Take driving and addressing by a voltage source as an example, when a column address signal and a row address signal together address a non-volatile memory cell of a memory block 50 of the memory array 40, the column decoder generates a column strobe signal according to the column address signal to activate a column line to provide operating voltage VDa to thereby allow unactivated column lines to provide voltage VDb, while the row decoder generates a row strobe signal according to the row address signal to activate row lines to provide operating voltages VGa and VSa to thereby allow unactivated row lines to provide voltages VGb and VSb. At this time, the column strobe signal and the row strobe signal controllably cause the column-enabling switch array 421 and the row-enabling switch array 422, which are connected to the operating memory block 50, to turn ON such that all the column-segment lines 51 and row-segment lines 52 of the operating memory block 50 are electrically connected to the column line 11 and row lines 21 respectively, allowing the activated column line 11 to activate corresponding ones of the column-segment lines 51, and allowing the activated row line 21 to activate corresponding ones of the row-segment lines 52. Therefore, the activated column-segment lines 51 and activated row-segment lines 52 enable one of the non-volatile memory cells of the operating memory block 50 to operate in one of a programming mode, an erasing mode and a reading mode. In the case where column-enabling switch arrays 421 and row-enabling switch arrays 422 are turned OFF, the memory cells of the other non-operating memory blocks 50 enter an idle state and thus are free of interference from the mode in which the operating memory block 50 is operating.

In an embodiment of the disclosure, a non-volatile memory (NVM) device performs an addressing method to address at least one of a plurality of non-volatile memory cells (NVM cells), and the plurality of non-volatile memory cells are divided into a plurality of memory blocks 50. Each non-volatile memory cell in each memory block 50 is electrically connected to a column-segment line 51 and at least one row-segment line 52. The addressing method comprises the steps of: generating, by a column decoder, a column strobe signal to activate a column line 11 according to a column address signal; generating, by a row decoder, a row strobe signal to activate a row line 21 according to a row address signal; controlling a column-enabling switch array 421 and a row-enabling switch array 422 according to the row strobe signal and the column strobe signal respectively to allow the activated column line 11 and the activated row line 21 to enable one of the memory blocks 50; controllably causing, by the column-enabling switch array 421, the column-segment lines 51 of the enabled memory block 50 to electrically connect to the column lines 11 respectively according to the row strobe signal; controllably causing, by the row-enabling switch array 422, the row-segment lines 52 of the enabled memory block 50 to electrically connect to the row lines 21 respectively according to the column strobe signal; and addressing at least one non-volatile memory cell of the enabled memory block 50 according to the activated column line 11 and the activated row line 21 to allow the at least one non-volatile memory cell to operate in one of a programming mode, an erasing mode and a reading mode.

In an embodiment of the disclosure, a memory array layout method performed by a non-volatile memory (NVM) device of the disclosure comprises the steps of: providing a plurality of column lines and a plurality of row lines on a metal layer of a substrate, wherein the plurality of column lines are parallel, and the plurality of row lines are parallel; and defining a plurality of memory blocks on a component layer of the substrate, the memory blocks each providing a plurality of non-volatile memory cells each disposed at the junction of a column line and a row line, wherein a plurality of column-segment lines corresponding in position to the column lines and a plurality of row-segment lines corresponding in position to the row lines are provided on the metal layer and correspond in position to the memory blocks respectively, and the non-volatile memory cells of the memory blocks are electrically connected to the column-segment lines and the row-segment lines respectively; and providing at least one column-enabling switch array and/or at least one row-enabling switch array between two adjacent ones of the memory blocks on the component layer, wherein the column-enabling switch array controllably causes a plurality of column-segment lines of the memory blocks to electrically connect to the column lines respectively, and the row-enabling switch array controllably causes a plurality of row-segment lines of the memory blocks to electrically connect to the row lines respectively.

In an embodiment of the disclosure, a memory control method performed by the non-volatile memory (NVM) device of the disclosure and adapted for use with a memory controller, comprises the steps of: controllably causing a row-enabling switch array of a memory block to turn ON according to a column strobe signal generated by a column address signal to allow a plurality of row-segment lines of the memory block to electrically connect to the row lines respectively; and controllably causing a column-enabling switch array of the memory block to turn ON according to a row strobe signal generated by a row address signal to allow a plurality of column-segment lines of the memory block to electrically connect to the column lines respectively, allowing the column line activated by the column strobe signal and the row line activated by the row strobe signal to address at least one non-volatile memory cell of the memory block and thus operate in one of a programming mode, an erasing mode and a reading mode.

In conclusion, the disclosure provides novel non-volatile memory cells, a novel non-volatile memory device, a system-on-chip comprising the novel non-volatile memory device and its novel addressing method, and a memory control method such that unaddressed and non-operating non-volatile memory cells or cell groups are free of interference from addressed and operating non-volatile memory cells or cell groups, enhancing the reliability of the stable operation of the memory array.

What is claimed is:

1. A non-volatile semiconductor memory device, comprising:
a plurality of column lines;
a plurality of row lines;
a column decoder for generating a column strobe signal to activate a column line according to a column address signal;
a row decoder for generating a row strobe signal to activate a row line according to a row address signal; and
a memory array comprising a plurality of non-volatile memory cells built around junctions of the column lines and the row lines respectively,
wherein the non-volatile memory cells are each coupled to one of the plurality of column lines via a column-enabling switch and coupled to one of the plurality of row lines via at least one row-enabling switch, the column-enabling switch allows the activated column line to enable the non-volatile memory cells according to the row strobe signal, and the row-enabling switch allows the activated row line to enable the non-volatile memory cells according to the column strobe signal, so as for the enabled non-volatile memory cells to operate in one of a programming mode, an erasing mode and a reading mode.

2. The non-volatile semiconductor memory device of claim 1, wherein the non-enabled non-volatile memory cells of the memory array, except for the enabled non-volatile memory cells of the memory array, are not electrically connected to the column lines that are unactivated or activated and the row lines that are unactivated or activated.

3. A system-on-chip, comprising:
the non-volatile semiconductor memory device of claim 1; and
a power source circuit electrically connected to the row decoder and the column decoder to provide a voltage or current required for the enabled non-volatile memory cells to operate in each of the modes.

4. An addressing method, for addressing at least one of a plurality of non-volatile memory cells (NVM cells), the plurality of non-volatile memory cells each corresponding to at least one column line and corresponding to at least one row line, the addressing method comprising the steps of:
generating a column strobe signal according to a column address signal to activate a column line;
generating a row strobe signal according to a row address signal to activate a row line;
enabling, by the column line, the at least one non-volatile memory cell according to the row strobe signal; and
enabling, by the row line, the at least one non-volatile memory cell according to the column strobe signal, allowing the at least one non-volatile memory cell to operate in one of a programming mode, an erasing mode and a reading mode.

5. A non-volatile semiconductor memory device, comprising:
a column decoder configured for generating a column strobe signal according to a column address signal to activate one of a plurality of column lines;
a row decoder configured for generating a row strobe signal according to a row address signal to activate one of a plurality of row lines; and
a memory array comprising a plurality of non-volatile memory cells divided into a plurality of memory blocks,
wherein each of the non-volatile memory cells in each of the memory blocks is electrically connected to a column-segment line and at least one row-segment line, and each of the memory blocks comprises a column-enabling switch array and a row-enabling switch array, the column-enabling switch array allows a part of the column lines to electrically connect to the column-segment lines of the memory blocks according to the row strobe signal, and the row-enabling switch array allows a part of the row lines to electrically connect to the row-segment lines of the memory blocks according to the column strobe signal.

6. The non-volatile semiconductor memory device of claim 5, wherein one of the memory blocks is enabled according to the column strobe signal and the row strobe signal, and at least one non-volatile memory cell of the enabled memory block is addressed according to the column line activated by the column strobe signal and the row line activated by the row strobe signal to operate in one of a programming mode, an erasing mode and a reading mode.

7. The non-volatile semiconductor memory device of claim 6, wherein the memory blocks not enabled are not electrically connected to the column lines that are unactivated or activated and the row lines that are unactivated or activated.

8. A system-on-chip, comprising:
the non-volatile semiconductor memory device of claim 5; and
a power source circuit electrically connected to the row decoder and the column decoder to provide a voltage or current required for the enabled memory block to operate in one of a programming mode, an erasing mode and a reading mode.

9. The system-on-chip of claim 8, further comprising a memory controller for controlling the column-enabling switch array to cause a part of the column lines to electrically connect to the column-segment lines of the memory blocks according to the row strobe signal and controlling the row-enabling switch array to cause a part of the row lines to electrically connect to the row-segment lines of the memory blocks according to the column strobe signal.

10. An addressing method, for addressing at least one of a plurality of non-volatile memory cells divided into a plurality of memory blocks each having therein non-volatile memory cells, each of the plurality of non-volatile memory cells electrically connected to a column-segment line and a row-segment line, the addressing method comprising the steps of:
generating a column strobe signal according to a column address signal to activate a column line;
generating a row strobe signal according to a row address signal to activate a row line;
enabling one of the memory blocks according to the column strobe signal and the row strobe signal;
electrically connecting a part of the column lines to the column-segment lines of the memory block according to the row strobe signal, and electrically connecting a part of the row lines to the row-segment lines of the memory block according to the column strobe signal; and
addressing, according to the activated column line and the activated row line, at least one non-volatile memory cell of the memory block to operate in one of a programming mode, an erasing mode and a reading mode.

11. The addressing method of claim 10, further comprising the step of providing a column-enabling switch array and a row-enabling switch array to each of the memory blocks, the column-enabling switch array controlling a part of the column lines to electrically connect to the column-segment lines of the memory block, and the row-enabling switch array controlling a part of the row lines to electrically connect to the row-segment lines of the memory block.

12. The addressing method of claim 10, further comprising the steps of:
controlling the column-enabling switch array of the memory block according to the row strobe signal to allow a part of the column lines to electrically connect to the column-segment lines of the memory block, wherein the a part of the column lines includes the activated column line; and
controlling the row-enabling switch array of the memory block according to the column strobe signal to allow a part of the row lines to electrically connect to the row-segment lines of the memory block, wherein the a part of the row lines includes the activated row line.

13. A memory array layout method, comprising the steps of:
arranging a plurality of column lines and a plurality of row lines of a metal layer of a substrate; and
defining a plurality of memory blocks of a component layer of the substrate, each of the memory blocks providing a plurality of non-volatile memory cells, each of plurality of non-volatile memory cells built around a junction of a column line and a row line,
wherein a plurality of column-segment lines and a plurality of row-segment lines are provided within the metal layer and correspond in position to the memory blocks respectively, and each of the non-volatile memory cells of the memory blocks are electrically connected to a corresponding column-segment line and a corresponding row-segment line,
wherein at least one column-enabling switch array and/or at least one row-enabling switch array is disposed within the component layer and between two adjacent ones of the memory blocks, and the column-enabling switch array controllably causes a part of the column lines to electrically connect to the column-segment lines of the memory blocks, while the row-enabling switch array controllably causes a part of the row lines to electrically connect to the row-segment lines of the memory blocks.

14. A memory control method, for controlling the non-volatile semiconductor memory device of claim 5, the memory control method comprising the steps of:
controlling the column-enabling switch array to cause a part of the column lines to electrically connect to the column-segment lines of the memory blocks according to the row strobe signal; and
controlling the row-enabling switch array to cause a part of the row lines to electrically connect to the row-segment lines of the memory blocks according to the column strobe signal.

15. The memory control method of claim 14, further comprising the step of controllably decreasing, upon completion of operation of at least one non-volatile memory cell of the memory blocks in one of a programming mode, an erasing mode and a reading mode, electric potential of the activated column line and the activated row line to 0V and then controllably causing the column-enabling switch and the row-enabling switch to turn OFF to allow the non-volatile memory cell to be electrically isolated from the column line and the row line and thus enter an idle state.
